(19) United States
(12) Patent Application Publication
(10) Pub. No.: US 2026/0040648 A1
(43) Pub. Date: Feb. 5, 2026

(54) III-Nitride Transistors with Field Plate and Methods of Fabrication

(71) Applicant: Finwave Semiconductor, Inc., Belmont, MA (US)

(72) Inventors: Hal Emmer, Wayland, MA (US); Sangmin Lee, Lawrence, MA (US)

(21) Appl. No.: 19/283,906

(22) Filed: Jul. 29, 2025

Related U.S. Application Data
(60) Provisional application No. 63/679,189, filed on Aug. 5, 2024.

(51) Int. Cl. H10D 64/00; H10D 30/01; H10D 30/47; H10D 62/85; H10D 64/01; H10D 64/27

(52) U.S. Cl. CPC H10D 64/112; H10D 30/015; H10D 30/475; H10D 62/8503; H10D 64/015; H10D 64/018; H10D 64/027; H10D 64/514; H10D 64/512

(57) ABSTRACT

A new semiconductor structure and method of fabrication is disclosed. The semiconductor structure includes a source-connected field plate, which in some embodiments, is located at least as close to the barrier layer as the gate field plate, if present. The source-connected field plate is formed by patterning the dielectric layer to create a cavity in which metal will be deposited to form the source-connected field plate. In some embodiments, there may be multiple source-connected field plates, which are each at a different distance from the barrier layer. These multiple source-connected field plates may be created using a single metal deposition process.

This application claims priority to U.S. Provisional Patent Application Ser. No. 63/679,189, filed Aug. 5, 2024, the disclosure of which is incorporated herein by reference in its entirety.

### FIELD

Embodiments of the present disclosure relate to methods for forming a field plate in a III-Nitride Transistor and the transistors that are produced using these methods.

### BACKGROUND

FIGS. 1A-1B show a typical conventional III-Nitride semiconductor transistor. FIG. 1A is a top view, while FIG. 1B is a cross-sectional view. The III-Nitride semiconductor transistor comprises a substrate 1, a buffer layer 2 on top of the substrate 1, a channel layer 3 on top of the buffer layer 2 and barrier layer 4 on top of the channel layer 3. The substrate 1 is SiC, sapphire, Si or free-standing GaN semiconductors. A nucleation layer exists between the buffer layer 2 and the substrate 1. The barrier layer 4, which may be made from AlGaN, has a wider band-gap than the channel layer 3, which may be made from GaN. Source electrode 7 and drain electrode 8 are disposed on opposite sides of the gate electrode 6 in the length direction. The direction that is orthogonal to the length direction and perpendicular to the page in FIG. 1B is referred to as the width direction. This is the vertical direction in FIG. 1A. Note that in the transistor, the two dimensional electron gas (2DEG) is disposed in the interface between the channel layer 3 and the barrier layer 4 and extends from the source electrode 7 to the drain electrode 8. Thus, this transistor conducts current between the source electrode 7 and the drain electrode 8 whenever the voltage applied to the gate electrode 6 is greater than a threshold voltage (Vth) of the transistor. A dielectric layer 5 may be disposed on top of the barrier layer 4. The dielectric layer 5 may be made of silicon oxide, silicon nitride, some other suitable material, or a stack of different materials.

In a conventional transistor with a source-connected field plate, such as is shown in FIG. 1B, the bottom surface of the source field plate 9 is located above the gate electrode 6, with a thicker dielectric layer 5 below the source-connected field plate 9 compared to the gate field plate 10. A first dielectric layer may be deposited, the first dielectric layer may be etched to form the gate cavity. The gate electrode 6 may then be formed in the gate cavity, and then a second dielectric layer may be deposited on top of the gate electrode 6. The source-connected field plate is then deposited on top of the second dielectric layer.

Thus, in this configuration, the source-connected field plate 9 is typically deposited and patterned separately from the gate electrode 6, either along with the source/drain metallization, or in a separate metal layer. The source-connected field plate 9 may overlap the gate electrode 6 or may be adjacent to the gate electrode 6 and connected to the source electrode 7 without overlapping the gate, as shown in FIG. 1B.

The addition of a source-connected field plate 9 reduces the electric field in the drain side access region, which results in many benefits, including improved breakdown voltage, reduced trapping resulting in improved current and dynamic behavior, and reduced gate to drain capacitance. Benefits are maximized when the source-connected field plate 9 is engineered to have the proper turn-off voltage, which requires control of the thicknesses of the dielectric layer 5. Additionally, optimal performance may be achieved in an RF device when the gate to source and the gate to drain capacitance are minimized. A gate connected field plate may not be beneficial in such devices, and the parasitic capacitances associated with the gate should be minimized.

In a conventional III-Nitride semiconductor transistor with field plates, additional field plate levels with increasing thicknesses of the dielectric layer 5 may be added by alternating additional dielectric and metal layers. However, in a conventional device, these are either connected to the gate electrode 6 or located above the gate electrode 6, with the lowest point of the field plate having thicker dielectric than the region surrounding the gate.

Therefore, it would be beneficial if there were an improved III-Nitride semiconductor transistor and a new method of forming field plates in these III-Nitride semiconductor transistors.

### SUMMARY

A new semiconductor structure and method of fabrication is disclosed. The semiconductor structure includes a source-connected field plate, which in some embodiments, is located at least as close to the barrier layer as the gate field plate, if present. The source-connected field plate is formed by patterning the dielectric layer to create a cavity in which metal will be deposited to form the source-connected field plate. In some embodiments, there may be multiple source-connected field plates, which are each at a different distance from the barrier layer. These multiple source-connected field plates may be created using a single metal deposition process.

According to one embodiment, a semiconductor transistor for use in a III-Nitride (III-N) semiconductor device is disclosed. The semiconductor transistor comprises a channel layer; a barrier layer located on the channel layer in a height direction; a dielectric layer disposed on the barrier layer; a source electrode and a drain electrode, wherein a direction between the source electrode and the drain electrode is a length direction; a gate electrode disposed between the source electrode and the drain electrode in the length direction and extending in a width direction, wherein a top portion of the gate electrode comprises a gate field plate disposed on a top surface of the dielectric layer and extending in the length direction; and a source-connected field plate disposed between the gate electrode and the drain electrode in the length direction, wherein a bottom surface of the source-connected field plate is a same distance or closer to the barrier layer than a bottom surface of the gate field plate.

In some embodiments, the bottom surface of the source-connected field plate is closer to the barrier layer than the bottom surface of the gate field plate. In certain embodiments, the dielectric layer comprises a first dielectric sublayer disposed on the barrier layer and a second dielectric sublayer, disposed above the first dielectric sublayer; and wherein the bottom surface of the source-connected field plate is beneath a top of the second dielectric sublayer. In certain embodiments, the first dielectric sublayer and the second dielectric sublayer are a same material. In certain embodiments, the first dielectric sublayer and the second dielectric sublayer are separated by an etch stop. In certain embodiments, the first dielectric sublayer and the second dielectric sublayer are different materials. In certain embodiments, a second source-connected field plate is disposed on the top surface of the dielectric layer. In certain embodiments, a spacer dielectric layer is disposed on top of a portion of the dielectric layer, wherein the spacer dielectric is also disposed along sidewalls between the gate electrode and the dielectric layer; and a third source-connected field plate is disposed on top of the spacer dielectric layer. In certain embodiments, the bottom surface of the source-connected field plate is aligned to a top of the barrier layer. In some embodiments, a cap layer is disposed between the barrier layer and the gate electrode.

According to another embodiment, a method of fabricating a III-Nitride semiconductor transistor is disclosed. The method comprises creating an assembly including a substrate, buffer layer, channel layer and a barrier layer; depositing a first dielectric sublayer on the barrier layer; depositing a second dielectric sublayer on the first dielectric sublayer; patterning and etching the second dielectric sublayer to create a cavity; and depositing metal into the cavity to form a source-connected field plate. In some embodiments, the method also comprises patterning and etching the first dielectric sublayer and the second dielectric sublayer to create a gate cavity; and depositing metal into the gate cavity so as to form a gate electrode at a same time as it is deposited into the cavity to form the source-connected field plate. In certain embodiments, the method also comprises depositing a spacer dielectric layer after the gate cavity is created; patterning and etching the spacer dielectric layer to form sidewalls in the gate cavity and leave spacer dielectric layer on a portion of the second dielectric sublayer; and depositing metal on top of the spacer dielectric layer to form a second source-connected field plate. In some embodiments, the method comprises depositing an etch stop on top of the first dielectric sublayer prior to depositing the second dielectric sublayer. In some embodiments, the first dielectric sublayer and the second dielectric sublayer are different materials. In some embodiments, the method also comprises depositing metal on top of the second dielectric sublayer to form a second source-connected field plate, wherein the source-connected field plate and the second source-connected field plate are formed using a same metallization step. In some embodiments, a cap layer is disposed in a gate region and a gate electrode is formed on the cap layer prior to the depositing of the first dielectric sublayer.

According to another embodiment, a method of fabricating a III-Nitride semiconductor transistor is disclosed. The method comprises creating an assembly including a substrate, buffer layer, channel layer and a barrier layer; depositing a dielectric layer on the barrier layer; patterning and etching the dielectric layer to create a gate cavity; and depositing metal into the gate cavity to form a gate electrode and on top of the dielectric layer to form a source-connected field plate, wherein the gate electrode and the source-connected field plate are created by a same metallization step. In some embodiments, the method also comprises depositing a spacer dielectric layer after the gate cavity is created; patterning the spacer dielectric layer to form sidewalls in the gate cavity and leave spacer dielectric layer on a portion of the dielectric layer; and depositing metal on top of the spacer dielectric layer to form a second source-connected field plate, wherein the second source-connected field plate is created by the same metallization step as the gate electrode and the source-connected field plate.

### BRIEF DESCRIPTION OF THE FIGURES

For a better understanding of the present disclosure, reference is made to the accompanying drawings, which are incorporated herein by reference and in which:

FIG. 1A shows a top view of a conventional III-Nitride transistor according to the prior art;

FIG. 1B shows a cross-section view of a conventional III-Nitride transistor according to the prior art;

FIGS. 2A-2B show cross-section views of two embodiments of the III-Nitride transistor;

FIGS. 3A-3B show cross-section views of two additional embodiments of the III-Nitride transistor;

FIG. 4 show a cross-section view of another embodiment of the III-Nitride transistor;

FIG. 5 show a cross-section view of another embodiment of the III-Nitride transistor;

FIGS. 6A-6B show cross-section views of other embodiments of the III-Nitride transistor using a spacer dielectric in the gate region;

FIG. 7 shows a first sequence to fabricate the III-Nitride transistors described herein; and

FIG. 8 shows a second sequence to fabricate the III-Nitride transistors described herein.

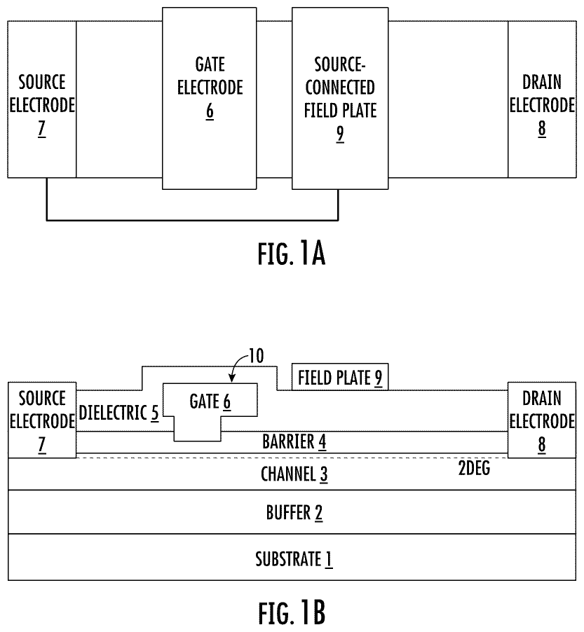

### DETAILED DESCRIPTION

This disclosure describes a semiconductor structure with a novel field plate and methods of creating this structure.

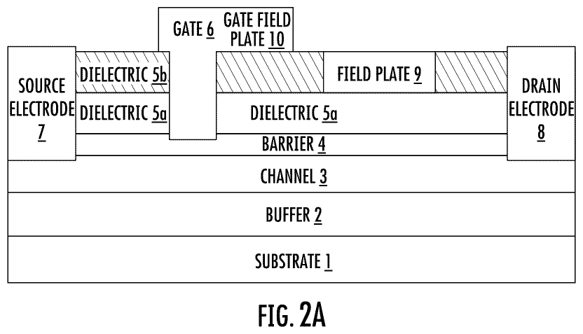

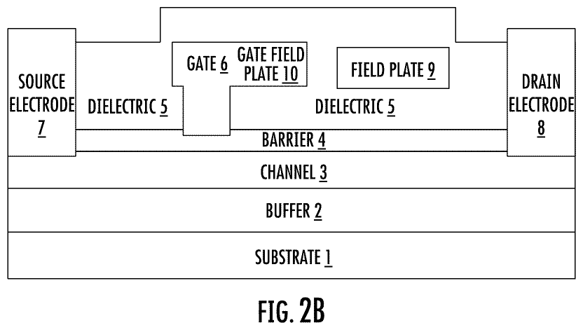

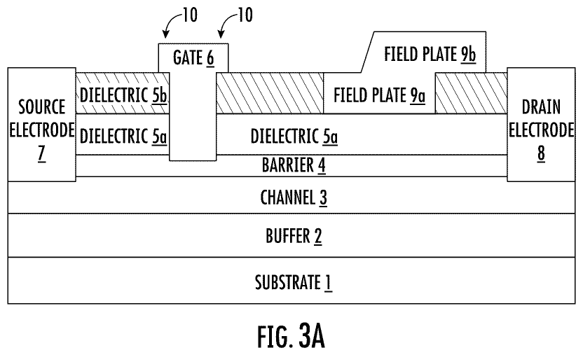

FIG. 2A shows a first embodiment. In this embodiment, a dielectric layer comprising two or more dielectric sublayers 5a, 5b are deposited. Afterwards, the dielectric material in one or more of these dielectric sublayers 5a, 5b is partially removed to form a cavity that will later be filled with metal to become the source-connected field plate 9 or field plates. At the same time, the dielectric material is also removed to form the gate cavity, which will later be filled with metal to become the gate electrode 6. Note that the depth of the gate cavity extends to or into the barrier layer 4. The depth of the cavity for the source-connected field plate 9 may extend to the top of the barrier layer 4 or to some distance smaller than that. In these embodiments, the cavity for the source-connected field plate 9 may extend completely through the second dielectric sublayer 5b. In some embodiments, the cavity may extend at least partly into the first dielectric sublayer 5a. In certain embodiments, the cavity may extend all the way to the bottom of the first dielectric sublayer 5a, such that it contacts the top of the barrier layer 4.

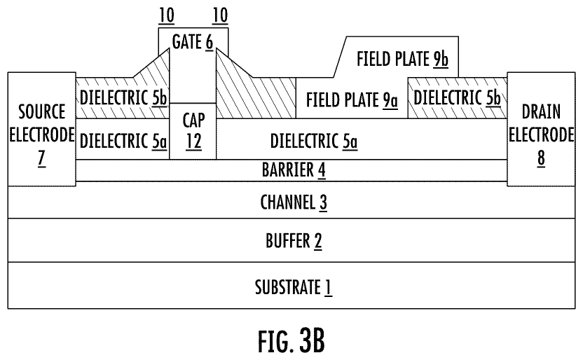

Later, the metal layer is applied to the cavities and both the gate electrode 6 and the source-connected field plate 9 are created at the same time. Note that because the metal for the gate electrode 6 is deposited into the gate cavity, there is typically some amount of gate metal that overhangs the gate cavity. In this disclosure, the term “gate field plate” is defined as metal disposed on top of the gate electrode 6 that extends further in the length direction than the gate electrode 6. This metal may be simply a small overhang (see, for example FIG. 3A), or may be enlarged such that a gate field plate 10 is formed at the top of the gate electrode 6 (see, for example, FIG. 2A). The bottom surface of this gate field plate 10 may be aligned with the top surface of the second dielectric sublayer 5b. Note that the bottom surface of the source-connected field plate 9 is closer to the barrier layer 4 than the bottom surface of the gate field plate 10. In other words, there is less dielectric material between the source-connected field plate 9 and the barrier layer 4 than between the gate field plate 10 and the barrier layer 4.

The thickness of the dielectric material under the source-connected field plate 9 in FIG. 2A may be controlled in several ways. Three examples include:
1. The same dielectric material may be used for first dielectric sublayer 5a and second dielectric sublayer 5b. An etch stop material such as aluminum oxide, aluminum nitride, or another suitable material, may be deposited at the thickness at which the bottom surface of the source-connected field plate 9 is to be located, between first dielectric sublayer 5a and second dielectric sublayer 5b to assist in controlling the thickness of first dielectric sublayer 5a after etching second dielectric sublayer 5b.
2. Different materials may be chosen for first dielectric sublayer 5a and second dielectric sublayer 5b such that a suitable selective etch recipe is available without employing an additional etch stop material. Examples include silicon nitride and silicon oxide, for which etches with high selectivity between these materials are well known.
3. The same dielectric material may be used for first dielectric sublayer 5a and second dielectric sublayer 5b. A timed etch may also be used to control the thickness of the dielectric material (also referred to as first dielectric sublayer 5a) that remains beneath source-connected field plate 9.

FIG. 2B shows another embodiment which does not utilize two sublayers. In this embodiment, a single dielectric layer 5 is deposited. Afterwards, the dielectric material is removed to form the gate cavity, which will later be filled with metal to become the gate electrode 6. Note that the depth of the gate cavity extends to or into the barrier layer 4. Later, the metal layer is applied to the gate cavity and both the gate electrode 6 and the source-connected field plate 9 are created at the same time. Note that the source-connected field plate 9 sits on top of the dielectric layer 5, and is the same distance from the barrier layer 4 as the gate field plate 10. An additional dielectric layer may then be deposited on top of the gate electrode 6 and the source-connected field plate 9.

Note that in the embodiments shown in FIGS. 2A-2B, the metal for the gate electrode 6, the gate field plate 10 (if present) and the source-connected field plate 9 is all deposited at the same time during the same metallization step. Further, in all of these embodiments, the source-connected field plate 9 is the same distance or closer to the barrier layer 4 than the bottom of the gate field plate 10.

FIG. 3A shows another embodiment where there are two source-connected field plates 9a, 9b. In this embodiment, the technique described above in FIG. 2A for creating a single source-connected field plate 9 is used. Thus, a cavity is created in the second dielectric sublayer 5b. However, rather than ending the metal deposition when the cavity is filled, which creates first source-connected field plate 9a, the metal layer is extended past the edge of the first source-connected field plate 9a toward the drain electrode 8. This additional metal is deposited on top of second dielectric sublayer 5b. This creates the second source-connected field plate 9b, which has a different thickness of dielectric material between it and the barrier layer 4. Specifically, the distance between the first source-connected field plate 9a and the barrier layer 4 is determined by the thickness of first dielectric sublayer 5a, while the distance between the second source-connected field plate 9b and the barrier layer 4 is determined by the combined thickness of the entire dielectric layer (i.e. dielectric sublayers 5a, 5b).

Further, while two source-connected field plates 9a, 9b are shown, additional field plates may be added by using additional dielectric sublayers separated by etch stop layers, of different dielectric materials and performing additional patterning and etch steps. Note that the number of dielectric sublayers may be equal to the number of source-connected field plates that are to be created (assuming the last source-connected field plate is disposed on the top of the combined dielectric layer). Using this method, the formation of N field plates with N different dielectric layer thicknesses requires N−1 patterning steps.

In another embodiment, shown in FIG. 3B, the gate of the transistor includes a cap layer 12 disposed on top of the barrier layer. The cap layer 12 may be Mg-doped GaN, or some other suitable material. In some embodiments, the dielectric sublayers 5a, 5b may be deposited after the cap layer 12 has been created. The dielectric sublayers 5a, 5b are then etched to expose the cap layer 12 and metal is deposited on top of this cap layer 12 to form the gate electrode 6. The rest of the sequence is as described above with respect to FIG. 2A. Note that, in this embodiment, as in the previous embodiments, the bottom surface of the first source-connected field plate 9a is located as same level as or closer to the barrier layer 4 than the bottom surface of the gate field plate 10.

Furthermore, more source-connected field plates may also be included, as described above.

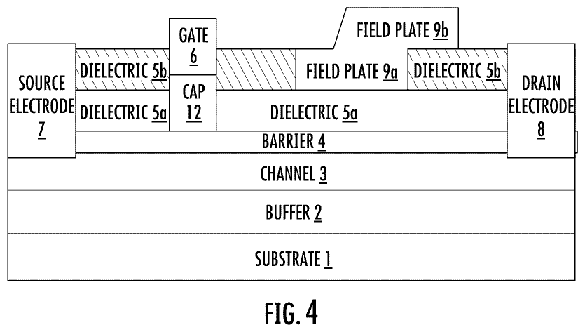

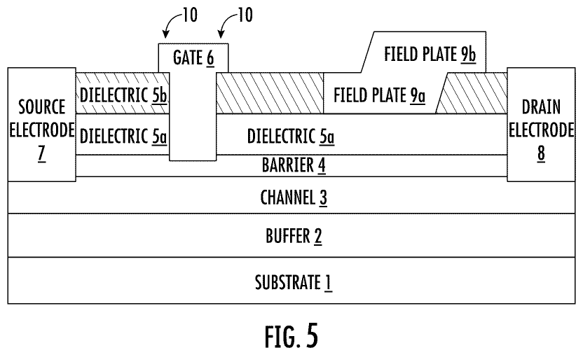

In another embodiment, shown in FIG. 4, the gate of the transistor includes the cap layer 12 as previously described in FIG. 3B. However, the gate electrode 6 is formed with a process such that it is self-aligned to the cap layer 12. In this way, there is no gate field plate 10. In this case, the dielectric sublayers 5a, 5b are deposited after the gate electrode 6 is formed and the source-connected field plate 9 described in this embodiment will be formed using a different metal layer than the gate electrode 6. However, as described above, the transistor comprises multiple source-connected field plates, each with a different effective dielectric thickness. Note that, as described above, these source-connected field plates 9a, 9b are formed using a single metal layer, with the thickness of the dielectric material beneath the first source-connected field plate 9a being smaller than the total combined thickness of all of the dielectric sublayers. Further, at least one of the source-connected field plates is formed in a cavity created by etching one or more of the dielectric sublayers 5a, 5b.

In one embodiment, the multiple source-connected field plates 9a, 9b may be created by forming at least a first cavity in the second dielectric sublayer 5b and then depositing metal in the first cavity and also on top of the second dielectric sublayer 5b to create the two source-connected field plates.

In embodiments which include more than two source-connected field plates, it is possible to deposit and pattern the metal for all of the source-connected field plates simultaneously after all the dielectric etching is complete. Note that three source-connected field plates may be created using three dielectric sublayers, wherein a first cavity extends through the first and second dielectric sublayers. A second cavity, which is larger than the first cavity in the length direction and overlaps the first cavity, extends through only the first dielectric sublayer. Metal is then deposited to fill the first cavity (at least to the level of the top of the second dielectric sublayer), the second cavity (to the top of the third dielectric sublayer) and also deposited on top of the third dielectric sublayer.

Furthermore, additional performance benefits may be obtained by using a shallow angle between first source-connected field plate 9a and second source-connected field plate 9b as shown in FIG. 5. Note that, if additional source-connected field plates are present, the shallow angle may be located between any pair of adjacent plates. This is possible because the step between the first source-connected field plate 9a and the second source-connected field plate 9b is formed by etching. This etch can be tuned for the desired sidewall angle using common etching techniques, as are known in the art.

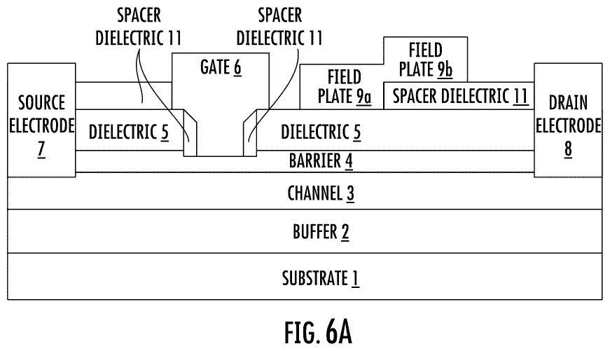

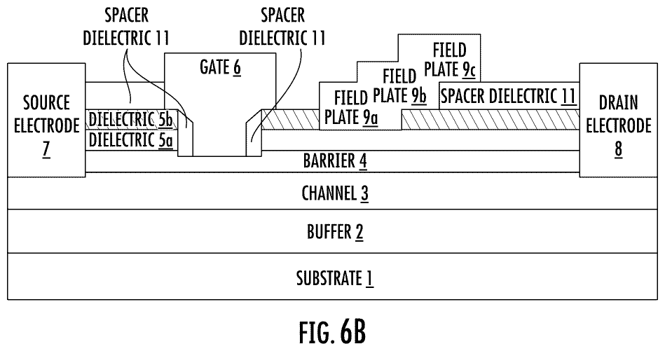

In another embodiment, shown in FIGS. 6A-6B, a spacer dielectric layer 11 is used as an additional dielectric layer to form a second source-connected field plate 9b. To make the gate opening length smaller, a spacer dielectric layer is used after the gate cavity is made through the dielectric layer 5. After spacer dielectric layer 11 is formed, an anisotropic plasma etching is done to remove spacer dielectric from the bottom of the gate cavity, leaving dielectric material on the side wall of the gate cavity. In a conventional process, this etching is done without patterning. In this embodiment of the disclosure, this etching is done with patterning to leave the spacer dielectric material on at least a portion of the top of the dielectric layer 5 on which the second source-connected field plate 9b will be disposed. As shown in FIG. 6A, the first source-connected field plate 9a and the second source-connected field plate 9b may be made with the same metallization process as the gate electrode 6. The gate electrode 6 extends into the barrier layer 4, while the first source-connected field plate 9a sits on the dielectric layer 5 and the second source-connected field plate 9b sits on the spacer dielectric layer 11.

In another embodiment, using two dielectric sublayers 5a, 5b as described in FIG. 2A, the first source-connected field plate 9a may be disposed closer to the barrier layer 4, as shown in FIG. 6B. In this embodiment, the gate electrode 6 extends into the barrier layer 4, while the first source-connected field plate 9a sits on the first dielectric sublayer 5a, the second source-connected field plate 9b sits on the second dielectric sublayer 5b and a third source-connected field plate 9c is disposed on the spacer dielectric layer 11.

This structure has many advantages. This technique overcomes limitations of the conventional field plate design by both minimizing gate capacitance and allowing the device designer to control the dielectric thickness under the source-connected field plate 9.

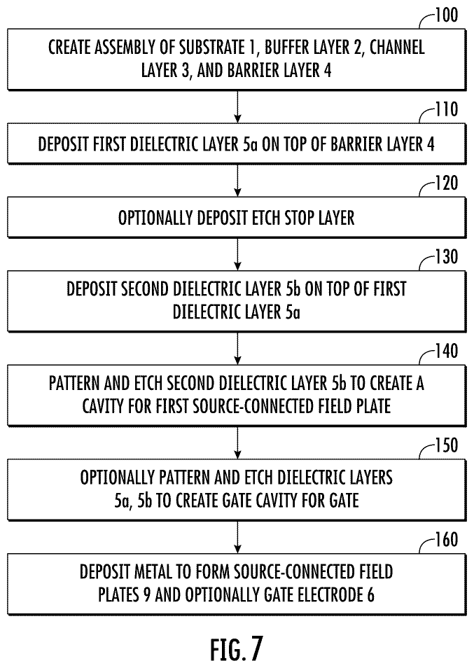

Additionally, an additional advantage of this disclosure is allowing a simple and streamlined fabrication process to be used. An example of this fabrication process is outlined in FIG. 7. This fabrication process applies to the transistors shown in FIGS. 2A, 3A-3B, 4, 5 and 6B. First, as shown in Box 100, an assembly or stack comprising the substrate 1, the buffer layer 2, the channel layer 3 and the barrier layer 4 is created. Next, as shown in Box 110, a first dielectric sublayer 5a is deposited on top of the barrier layer 4. Optionally, an etch stop is deposited on top of the first dielectric sublayer 5a, as shown in Box 120. A second dielectric sublayer 5b is then deposited on top of the first dielectric sublayer 5a, as shown in Box 130. The combination of dielectric sublayers forms the dielectric layer 5. The second dielectric sublayer 5b is then patterned and etched to create a cavity in which the source-connected field plate will be formed, as shown in Box 140. Optionally, for the embodiments shown in FIGS. 2A, 3A-3B, 5 and 6A, the first dielectric sublayer 5a and the second dielectric sublayer 5b are patterned and etched to form the gate cavity, as shown in Box 150. Note that for the embodiment shown in FIG. 4, the gate electrode 6 is already created before Box 110. Finally, metal is deposited into the cavity for the source-connected field plate and the gate cavity, as shown in Box 160. Note that if more than 2 field plates are desired, Boxes 120-130 may be performed iteratively. After the entirety of the dielectric layer 5 has been created, Box 140 may be performed iteratively to create the cavities for each of the source-connected field plates.

Additionally, note that for the embodiments shown in FIGS. 3A-3B, 4 and 5, the plurality of source-connected field plates are created using a single metal deposition process.

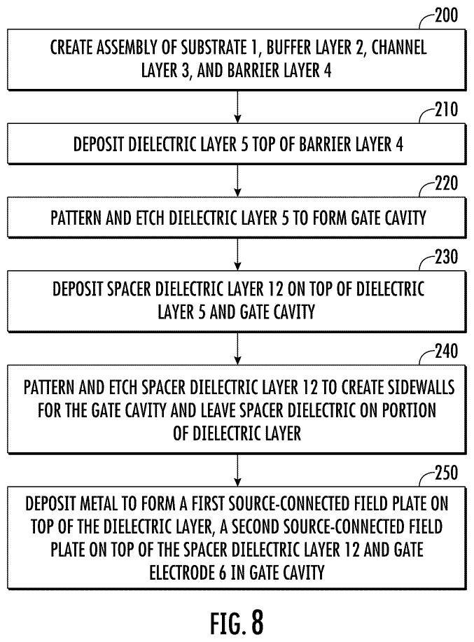

FIG. 8 shows the process that may be used for the transistors shown in FIGS. 6A-6B. First, as shown in Box 200, an assembly or stack comprising the substrate 1, the buffer layer 2, the channel layer 3 and the barrier layer 4 is created. Next, as shown in Box 210, a dielectric layer 5 is deposited on top of the barrier layer 4. Note that, in the embodiment of FIG. 6B, the dielectric layer 5 may comprise two or more dielectric sublayers 5a, 5b where an etch stop is optionally deposited between the dielectric sublayers 5a, 5b, as described above. The dielectric layer 5 is then etched to form the gate cavity, as shown in Box 220. A spacer dielectric layer 11 is then deposited on top of the dielectric layer 5 and the gate cavity, as shown in Box 230. The spacer dielectric layer 11 is then patterned and etched to create sidewalls in the gate cavity and leave the spacer dielectric layer 11 disposed on a portion of the dielectric layer 5, as shown in Box 240. Finally, as shown in Box 250, metal is deposited into the gate cavity for the gate electrode 6 and on top of the spacer dielectric layer 11 for the second source-connected field plate 9b. Note that the first source-connected field plate 9a may be disposed on top of the dielectric layer 5, or in the case of multiple dielectric sublayers, in a cavity formed in the dielectric layer 5.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A semiconductor transistor for use in a III-Nitride (III-N) semiconductor device, comprising:
a channel layer;
a barrier layer located on the channel layer in a height direction;
a dielectric layer disposed on the barrier layer;
a source electrode and a drain electrode, wherein a direction between the source electrode and the drain electrode is a length direction;
a gate electrode disposed between the source electrode and the drain electrode in the length direction and extending in a width direction, wherein a top portion of the gate electrode comprises a gate field plate disposed on a top surface of the dielectric layer and extending in the length direction; and
a source-connected field plate disposed between the gate electrode and the drain electrode in the length direction, wherein a bottom surface of the source-connected field plate is a same distance or closer to the barrier layer than a bottom surface of the gate field plate.

2. The semiconductor transistor of claim 1, wherein the bottom surface of the source-connected field plate is closer to the barrier layer than the bottom surface of the gate field plate.

3. The semiconductor transistor of claim 2, wherein the dielectric layer comprises a first dielectric sublayer disposed on the barrier layer and a second dielectric sublayer, disposed above the first dielectric sublayer; and wherein the bottom surface of the source-connected field plate is beneath a top of the second dielectric sublayer.

4. The semiconductor transistor of claim 3, wherein the first dielectric sublayer and the second dielectric sublayer are a same material.

5. The semiconductor transistor of claim 4, wherein the first dielectric sublayer and the second dielectric sublayer are separated by an etch stop.

6. The semiconductor transistor of claim 3, wherein the first dielectric sublayer and the second dielectric sublayer are different materials.

7. The semiconductor transistor of claim 2, further comprising a second source-connected field plate, wherein the second source-connected field plate is disposed on the top surface of the dielectric layer.

8. The semiconductor transistor of claim 7, further comprising:
a spacer dielectric layer disposed on top of a portion of the dielectric layer, wherein the spacer dielectric is also disposed along sidewalls between the gate electrode and the dielectric layer; and
a third source-connected field plate disposed on top of the spacer dielectric layer.

9. The semiconductor transistor of claim 2, wherein the bottom surface of the source-connected field plate is aligned to a top of the barrier layer.

10. The semiconductor transistor of claim 1, further comprising a cap layer disposed between the barrier layer and the gate electrode.

11. The semiconductor transistor of claim 1, further comprising:
a spacer dielectric layer disposed on top of a portion of the dielectric layer, wherein the spacer dielectric is also disposed along sidewalls between the gate electrode and the dielectric layer; and
a second source-connected field plate disposed on top of the spacer dielectric layer.

12. A method of fabricating a III-Nitride semiconductor transistor, comprising:
creating an assembly including a substrate, buffer layer, channel layer and a barrier layer;
depositing a first dielectric sublayer on the barrier layer;
depositing a second dielectric sublayer on the first dielectric sublayer;
patterning and etching the second dielectric sublayer to create a cavity; and
depositing metal into the cavity to form a source-connected field plate.

13. The method of claim 12, further comprising:
patterning and etching the first dielectric sublayer and the second dielectric sublayer to create a gate cavity; and
depositing metal into the gate cavity so as to form a gate electrode at a same time as it is deposited into the cavity to form the source-connected field plate.

14. The method of claim 13, further comprising:
depositing a spacer dielectric layer after the gate cavity is created;
patterning and etching the spacer dielectric layer to form sidewalls in the gate cavity and leave spacer dielectric layer on a portion of the second dielectric sublayer; and
depositing metal on top of the spacer dielectric layer to form a second source-connected field plate.

15. The method of claim 12, further comprising depositing an etch stop on top of the first dielectric sublayer prior to depositing the second dielectric sublayer.

16. The method of claim 12, wherein the first dielectric sublayer and the second dielectric sublayer are different materials.

17. The method of claim 12, further comprising depositing metal on top of the second dielectric sublayer to form a second source-connected field plate, wherein the source-connected field plate and the second source-connected field plate are formed using a same metallization step.

18. The method of claim 12, wherein a cap layer is disposed in a gate region and a gate electrode is formed on the cap layer prior to the depositing of the first dielectric sublayer.

19. A method of fabricating a III-Nitride semiconductor transistor, comprising:
creating an assembly including a substrate, buffer layer, channel layer and a barrier layer;
depositing a dielectric layer on the barrier layer;
patterning and etching the dielectric layer to create a gate cavity; and
depositing metal into the gate cavity to form a gate electrode and on top of the dielectric layer to form a source-connected field plate, wherein the gate electrode and the source-connected field plate are created by a same metallization step.

20. The method of claim 19, further comprising:
depositing a spacer dielectric layer after the gate cavity is created;
patterning the spacer dielectric layer to form sidewalls in the gate cavity and leave spacer dielectric layer on a portion of the dielectric layer; and
depositing metal on top of the spacer dielectric layer to form a second source-connected field plate, wherein the second source-connected field plate is created by the same metallization step as the gate electrode and the source-connected field plate.
